(19) United States
(12) Patent Application Publication
(10) Pub. No.: US 2008/0241575 A1
(43) Pub. Date: Oct. 2, 2008

(54) SELECTIVE ALUMINUM DOPING OF COPPER INTERCONNECTS AND STRUCTURES FORMED THEREBY

(76) Inventors: Adrein R. Lavoie, Beaverton, OR (US); Valery Dubin, Portland, OR (US); John Plombon, Portland, OR (US); Kari Harkonen, Kauniainen (FI); Arnel M. Fajardo, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/692,330

(22) Filed: Mar. 28, 2007

(51) Int. Cl. H01L 29/12; H01L 21/311

(52) U.S. Cl. 428/620; 257/E21.002; 438/778

(57) ABSTRACT

Methods and associated structures of forming a microelectronic device are described. Those methods may include heating a substrate comprising a patterned metallic region to about 145 C or below in a reaction space, introducing an aluminum co-reactant into the reaction space, wherein an aluminum material is formed on the patterned metallic region, but not on non-metallic regions.

### BACK GROUND OF THE INVENTION

The increased density of modern interconnect structures, which may comprise a high surface area coupled with a low metal volume, can lead to higher concentrations of dislodged ions due to the electromigration mechanism, as is known in the art. Electromigration may occur as a function of decreased interconnect dimensions, thus, as geometries get smaller in microelectronic devices, electromigration may increase. Aluminum metal deposition can reduce electromigration in dual damascene copper lines, however, aluminum deposition is achieved on all copper line surfaces and within the bulk of the copper line when the conventional deposition techniques are used.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1d represent structures according to an embodiment of the present invention.

FIGS. 2a-2d represent structures according to an embodiment of the present invention.

FIGS. 3a-3e represent structures according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may include heating a substrate comprising a patterned metallic region to about 145 C or below in a reaction space, introducing an aluminum co-reactant into the reaction space, wherein an aluminum material is formed on the patterned metallic region, but not on non-metallic regions. Embodiments of the present invention greatly improve circuit reliability of microelectronic devices so fabricate due to a reduction in electromigration and improvement in conformal coverage, symmetry, and thickness control of aluminum film formation.

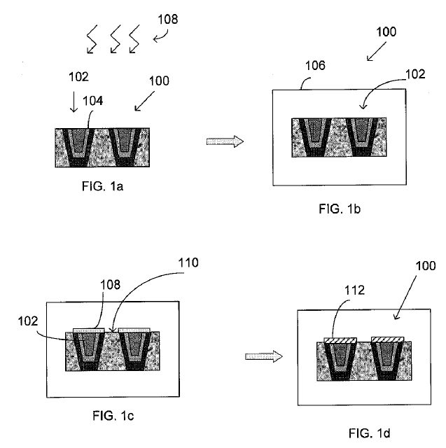

FIGS. 1a-1d illustrate an embodiment of a method of forming a microelectronic structure, such as a dual damascene copper line or copper interconnect structure, for example. FIG. 1a illustrates a cross-section of a portion of a substrate 100. The substrate 100 may be comprised of materials such as, but not limited to, silicon, silicon-on-insulator, germanium, indium antimonide, lead telluride, indium arsenide, indium phosphide, gallium arsenide, gallium antimonide, or combinations thereof. In one embodiment, the substrate 100 may include various devices (not shown) that, together, form a microprocessor. In an embodiment, the substrate 100 may include devices that together form multiple microprocessor cores on a single die.

In one embodiment, the substrate 100 may further comprise at least one patterned metallic structure 102. In one embodiment, the at least one patterned metallic structure 102 may comprise at least one of copper, copper alloy, copper oxide, copper nitride, nickel, cobalt, tungsten, molybdenum, ruthenium, osmium, rhodium, iridium, palladium, platinum, gold and silver. In one embodiment, the at least one patterned metallic structure 102 may comprise an interconnect structure, such as but not limited to a copper interconnect structure. The at least one patterned interconnect structure 102 may comprise at least one barrier layer 104, such as titanium and tantalum, for example.

In one embodiment, the substrate 100 may be optionally annealed 108. In one embodiment, the anneal 108 may comprise a temperature from about 140 degrees Celsius to about 300 degrees Celsius. In one embodiment the anneal 108 may be performed in inert gas flow (like nitrogen or argon flow) at reduced pressure. In one embodiment, during the anneal 108 additional forming gas (4% H2/Ar) may be used. Annealing the substrate 100 may serve to decrease residual contamination (such as moisture) that may be introduced when the substrate is placed inside a reaction space 106 (FIG. 1b) and/or on/in the substrate 100 from a previous process step, for example. Alternatively, the reaction space 106 may comprise a multi-chamber processing tool, as is known in the art, that may operate in such as manner as to prevent the substrate 100 from being exposed to air prior to a deposition process step.

The use of the forming gas during the anneal 108 may serve to reduce the surface of the patterned metallic structure 102. In another embodiment, a clean process may be optionally performed on the substrate 100, wherein a plasma and/or by an effective cleaning chemical (e.g. gas) may be utilized, as are known in the art.

In one embodiment, the substrate 100 may be placed in the reaction space 106 (FIG. 1b). In one embodiment, the reaction space 106 may comprise at least one of a single wafer physical vapor deposition system and a multi-wafer physical vapor deposition system. In one embodiment, the reaction space 106 may comprise at least one of a chemical vapor deposition (CVD) tool, a metal organic chemical vapor deposition (MOCVD) tool, and an atomic layer deposition (ALD) tool.

The substrate 100 may be heated to a temperature of about 145 degrees Celsius or below. In some embodiments, the temperature of heating may comprise below about 135 Celsius, in others, about 118 degrees Celsius, about 100 and about 85 degrees Celsius. An aluminum co-reactant may be introduced into the reaction space 106. In one embodiment, the aluminum co-reactant may comprise at least one of Methylpyrrolidinealane (MPA), Aluminum s-butoxide, Trimethylaluminum (AlMe₃ or TMA), Triethylaluminum (AlEt₃ or TEA), Di-i-butylaluminum chloride, Di-i-butylaluminum hydride, Diethylaluminum chloride, Tri-i-butylaluminum, and Triethyl(tri-sec-butoxy)dialuminum.

In one embodiment, the aluminum co-reactant may comprise an organometallic aluminum-compound comprising the formula H₃Al, H₃Al:L or H(R)₂Al:L, wherein Al is aluminum, H is hydrogen, R is an alkyl or perfluoroalkyl group having 1 to 4 carbons, and L is a Lewis base. In one embodiment R may comprise i-butyl and in one embodiment aluminum co-reactant may comprise di-(i-butyl) aluminum hydride (DIBAH). In one embodiment L may comprise 1,4-Methylpyrrolidine and in one embodiment aluminum co-reactant may comprise methylpyrrolidinealane (MPA). The Al—H bond is very reactive, which facilitates a low deposition temperature. In one embodiment, MPA, for example, can be transferred onto the substrate 100 using at least one of thermal energy, pressure difference, carrier gas and liquid dosing. Typical source temperature for MPA is about 25 degrees Celsius to about 50 degrees Celsius.

The aluminum co-reactant may react and/or decompose at the patterned metallic structure 102 surface, and in this manner may form an aluminum material 108 on the patterned metallic structure 102 (FIG. 1c). In one embodiment, the aluminum material 108 may be selectively formed on the patterned metallic structure 102, and may not be formed on other surrounding non-metallic regions 110, such as on dielectric materials, for example.

Aluminum deposition is typically achieved on all substrate 100 surfaces when conventional CVD/MOCVD processes are used. This happens because the deposition is controlled by thermal decomposition of aluminum co-reactants, such as MPA for example, without major impact from chemical composition of the substrate surface. Utilizing a lowered temperature (below about 145 degrees Celsius) ensures that aluminum material 108 formation occurs on patterned metallic structures 102, and not on non-metallic regions 110.

In one embodiment, the required formation temperature of the aluminum material 108 is lowered by an activation effect of the patterned metallic structure 102. In one embodiment, the aluminum material may comprise a thickness of about a monolayer to about 30 nm. In one embodiment for example, the metallic material of the patterned metallic structure 102, such as but not limited to copper, may diffuse continuously onto the surface of patterned metallic structure 102 to activate it or, in other embodiments, a fresh aluminum material 108 surface itself may decrease the temperature that is needed for deposition.

The lowered temperature of formation of the aluminum material 108 may result in the metallic material of the patterned metallic structure 102 primarily remaining continuous i.e., it is not harmed by temperature effects, for example, material agglomeration etc. Additionally, since the aluminum material 108 is selectively grown on the patterned metallic structure 102, there is no need for aluminum material 108 patterning, thus eliminating processing steps.

In one embodiment, composition of the aluminum material 108 can be tuned by varying the concentrations of the aluminum co-reactant and the patterned metallic structure 102. Thus, by tuning the stoichiometry of the aluminum material 108, it may form various alloys 112 (FIG. 1d) of various relative concentrations with the patterned metallic structure 102. The resistivity of the patterned metallic structure 102 can be tuned according to the particular application. In one embodiment, the aluminum material 108 may comprise a copper percentage of about 0 to about 50 percent and an aluminum concentration of about 50 to about 100 percent, and may comprise a resistivity below about 30 micro-Ohm-cm. (Aluminum doping of dual damascene copper lines usually results in a copper line resistivity increase by about 5 to 7%). Lowering the resistivity, but not having as much copper in the bulk of the line, may result in improved electromigration performance of devices fabricated according to embodiments of the present invention.

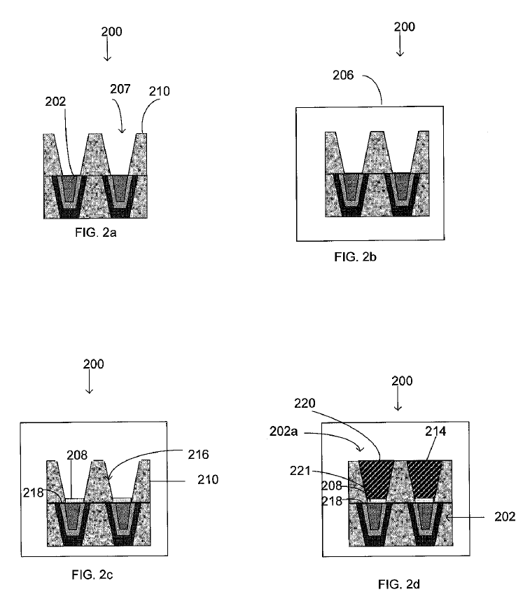

FIG. 2a-2d depict selective deposition of aluminum material on a patterned metallic substrate after lithographic patterning of an ILD layer prior to subsequent metal layer formation. FIG. 2a depicts a substrate 200, comprising at least one patterned metallic structure 202, an ILD 210 (inter-dielectric layer) and at least one opening 207. The at least one opening 207 may comprise a via of a damascene structure, as is known in the art, in some embodiments.

The substrate 200 may be placed in a reaction space 206 and an aluminum material 208 may be formed on a top surface 218 of the at least one patterned metallic structure 202 (FIGS. 2b-2c), but not on a sidewall portion 216 of the ILD 210, according to embodiments of the present invention. A fill material 220, such as a copper fill material, may be formed within the at least one opening 207 (FIG. 2d). The copper fill material 220 may comprise a portion of a second patterned metallic structure 202a, similar to the patterned metallic structure 202, and may comprise various barrier layers (not shown), similar to the barrier layers 104 of the patterned metallic structure 202 and 102 of FIG. 1a, for example.

The aluminum material 208 may be disposed between the top surface 218 of the patterned metallic structure 202 and a bottom surface 221 of the patterned metallic structure 202a, but will not be disposed on the sidewall portion of the patterned metallic structure 202a, since the aluminum material 208 only reacts with the exposed metallic portion of the patterned metallic structure 202, and not the ILD 210 sidewall 216, which is a non-metallic material.

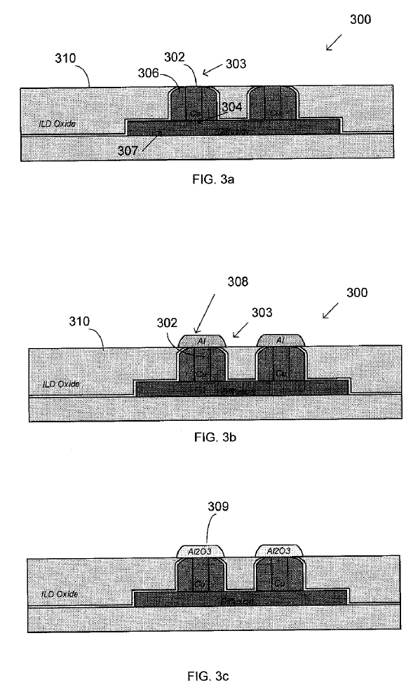

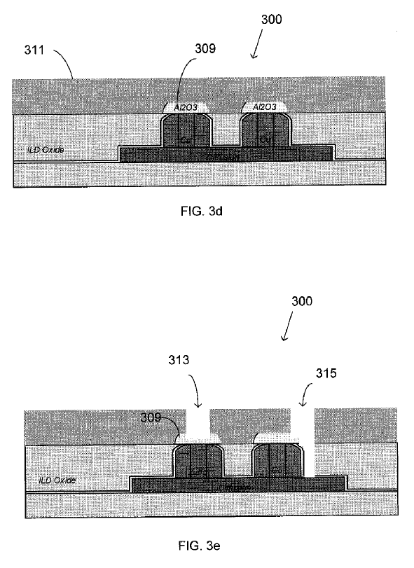

In another embodiment, a transistor structure 300 may comprise a patterned metallic structure 302 (similar to the patterned metallic structures 102, 202), that may comprise a portion of a gate structure 303, in some embodiments (FIG. 3a). In one embodiment, the patterned metallic structure 302 may comprise a portion of copper gate structure. The transistor structure 300 may further comprise a gate dielectric 304, sidewall spacers 306 disposed adjacent sidewalls of the gate structure 303 and a diffusion region 307 that may comprise various elements such as source/drain regions and channel regions, as are known in the art.

The transistor structure 300 may further comprise an ILD region 310. An aluminum material 308 may be formed on the patterned metallic structure 302 of the gate structure 303, and not substantially on the ILD region 310, according to embodiments of the present invention (FIG. 3b). The aluminum material 308 may be oxidized to form an aluminum oxide cap 309 (FIG. 3c). A dielectric layer 311, which may comprise a second ILD layer in some embodiments, may be formed on the aluminum oxide cap 309 (FIG. 3d). The dielectric layer 311 may be etched to form at least one of a gate contact opening 313 and a source/drain contact opening 315 FIG. 3e).

The gate contact opening 313 and the source/drain contact opening 315 may be subsequently filled with a conductive material (not shown), to form a conductive gate contact structure and a conductive source/drain contact structure. The aluminum oxide cap 309 may serve as an etch stop layer during processing of the gate contact structure and/or the source drain contact structure. The aluminum oxide cap 309 may be hermetic toward oxygen diffusion, thus protecting the underlying gate materials from oxidation in downstream processing. The aluminum oxide cap 309 may further serve as a dielectric material to mitigate any shorting of the gate contact with the source/drain contact, as may be encountered in case of marginal registration during lithographic patterning.

Benefits of the embodiments of the present invention enable selective deposition of metallic films or bulk materials via CVD or ALD thus yielding conformal coverage of such films. For example, thin copper and copper-aluminum alloy films may be formed selectively, thus eliminating process steps such as patterning of the aluminum films. Embodiments of the present invention enable Increased circuit reliability due to a reduction in electromigration effects, and improved conformal coverage, symmetry, and thickness control.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic structures are well known in the art. Therefore, it is appreciated that the Figures provided herein illustrate only portions of an exemplary microelectronic structures that pertains to the practice of the present invention. Thus the present invention is not limited to the structures described herein.

What is claimed is:

1. A method comprising:
heating a substrate comprising a patterned metallic structure to about 145 C or below in a reaction space;
introducing an aluminum co-reactant into the reaction space, wherein an aluminum material is formed on the patterned metallic structure, but not on non-metallic regions.

2. The method of claim 1 further comprising wherein the patterned metallic structure comprises at least one of copper, copper alloy, copper oxide, copper nitride, nickel, cobalt, tungsten, molybdenum, ruthenium, osmium, rhodium, iridium, palladium, platinum, gold and silver.

3. The method of claim 1 further comprising wherein the aluminum co-reactant comprises at least one aluminum-hydrogen bond, and wherein the aluminum co-reactant comprises at least one of di-(i-butyl) aluminum hydride (DIBAH), methylpyrrolidine alane (MPA), Aluminum s-butoxide, Trimethylaluminum (AlMe₃ or TMA), Triethylaluminum (AlEt₃ or TEA), Di-i-butylaluminum chloride, Di-i-butylaluminum hydride, Diethylaluminum chloride, Tri-i-butylaluminum, and Triethyl(tri-sec-butoxy)dialuminum.

4. The method of claim 1 further comprising annealing the substrate prior to cooling at a temperature of about 140 to about 300 degrees Celsius, and wherein annealing is operated at a reduced pressure with inert gas and wherein additional forming gas is used.

5. The method of claim 1 wherein an aluminum material is formed on the patterned metallic substrate, but not on non-metallic regions comprises wherein an aluminum material is formed on the patterned metallic structure, but not on dielectric regions.

6. The method of claim 1 further comprising wherein the patterned metallic structure comprises a portion of a copper gate structure and further comprising:
oxidizing the aluminum material to form an aluminum oxide cap;
forming a dielectric layer on the aluminum cap; and
etching a gate contact opening and a source/drain contact opening in the dielectric layer.

7. The method of claim 6 further comprising wherein the aluminum material is not disposed on a sidewall of the copper gate structure.

8. The method of claim 1 wherein the aluminum material is formed by at least one of CVD, MOCVD and ALD.

9. A structure comprising:
a substrate comprising a patterned metallic region, wherein an aluminum material is disposed on at least one of a top surface and a bottom surface of the patterned metallic region, but is not disposed on a sidewall region of the patterned metallic region.

10. The structure of claim 9 wherein the patterned metal region comprises at least one of copper, copper alloy, copper oxide, copper nitride, nickel, cobalt, tungsten, molybdenum, ruthenium, osmium, rhodium, iridium, palladium, platinum, gold and silver.

11. The structure of claim 9 wherein the aluminum material comprises a copper percentage of about 0 to about 50 percent and an aluminum concentration of about 50 to about 100 percent.

12. The structure of claim 9 wherein the patterned metallic region comprises a copper interconnect structure, and the aluminum material is disposed on at least one of a top surface and a bottom surface of the copper interconnect structure.

13. The structure of claim 9 wherein the patterned metallic region comprises a portion of a copper gate contact, and the aluminum material comprises an aluminum oxide.

14. The structure of claim 14 wherein the aluminum oxide comprises an etch stop layer.

15. The structure of claim 9 wherein the resistivity comprises below about 30 micro-Ohm-cm.
